(19) United States
(12) Patent Application Publication
(10) Pub. No.: US 2019/0114982 A1
(43) Pub. Date: Apr. 18, 2019

(54) DISPLAY PANEL AND GATE SIGNAL CONTROL METHOD FOR DISPLAY PANEL

(71) Applicant: Shenzhen China Star Optoelectronics Semiconductor Display Technology Co., Ltd., Shenzhen, Guangdong (CN)

(72) Inventor: Xianming ZHANG, Shenzhen, Guangdong (CN)

(21) Appl. No.: 15/735,720

(22) PCT Filed: Nov. 6, 2017
(86) PCT No.: PCT/CN2017/109529

§ 371 Date: Dec. 12, 2017

(30) Foreign Application Priority Data
Jul. 19, 2017 (CN) 201710592931.9

(51) Int. Cl. G09G 3/36

(52) U.S. Cl. CPC G09G 3/3677; G09G 2310/06; H03K 19/017509; G09G 2310/027; G09G 2310/0289

(57) ABSTRACT

The present disclosure provides a display panel and a gate signal control method for the display panel. The display panel includes a gate driving substrate, a plurality of gate driving units, a level shifter, and a driving circuit. A control end of the driving circuit is coupled to an output end of the level shifter. An output end of the voltage control circuit is coupled to an input end of the driving circuit. The voltage control circuit is configured to set different output voltages applied to the pixel units to correspond to the signals outputted from the driving circuit, for making on and off frequencies of the input end and the output end of the driving circuit increase row by row.

### FIELD OF INVENTION

The present disclosure relates to the field of liquid crystal displays, and more particularly to a GOA driving circuit and a liquid display panel.

### BACKGROUND OF INVENTION

Present display panels include liquid crystal display (LCD) panels and organic light emitting display (OLED) panels. OLED display panels have become the display devices having the highest developmental potential due to their advantages, such as self-illumination, low driving voltage, high illumination efficiency, short response times, high definition and high contrast, nearly 180 degree viewing angle, wide operating temperatures, flexible display, large full-color display area, etc.

Gate on array (GOA) utilize thin film transistors (TFTs) in the TFT-LCD and level shifters (level shifter ICs) on a circuit board to generate required gate signals. This method can efficiently reduce number of gate ICs and reduce costs.

However, this method may cause parasitic resistance and parasitic capacitance in the IC. Difference between the distant resistance and close resistance is particularly large. This situation may cause a huge difference between the distant and close gate signals in the panel.

### SUMMARY OF INVENTION

The object of this disclosure is to provide a display panel and a gate signal control method for a display panel in order to improve the difference of gate signals between the distant end and close end.

To reach the above-mentioned object, the pixel driving circuit of the present disclosure adopts the following technique.

A display panel, comprising:
a gate driving substrate comprising a pixel array and a circuit laying area located by the pixel array, the pixel array comprising pixel units arranged in rows;
a plurality of gate driving units disposed on the circuit laying area, and configured to output scanning signals to the pixel units of the pixel array;
a level shifter coupled to the plurality of gate driving units and configured to output a control signal;
a driving circuit comprising an input end, an output end coupled to the pixel units through the gate driving units, and a control end coupled to an output end of the level shifter for controlling the input end and the output end of the driving circuit to be on or off;
a voltage control circuit comprising an output end coupled to the input end of the driving circuit, and configured to set different voltages inputted into the input end of the driving circuit according to the pixel units to correspond to a signal outputted from the driving circuit, for making on and off frequencies of the input end and the output end of the driving circuit increase row by row; wherein the voltage control circuit comprises:
a digital-to-analog converter configured to set different adjusting voltages to the pixel units to correspond to the signals outputted from the driving circuit, for making on and off frequencies of the input end and the output end of the driving circuit increase row by row;
a digital voltage generator comprising an output end coupled to the input end of the driving circuit and configured to set different output voltages applied to the pixel units to correspond to the signals outputted from the driving circuit, for making on and off frequencies of the input end and the output end of the driving circuit increase row by row; and
an adder comprising an output end coupled to the input end of the driving circuit, a first input end receiving a reference voltage, and a second input end coupled to the digital-to-analog converter.

In the display panel of present disclosure, the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein an input end of the PMOS transistor is coupled to the output end of the voltage control circuit, and/or an input end of the NMOS transistor is coupled to the output end of the driving circuit, for setting different adjusting voltages applied to the pixel units to correspond to the signals outputted from the driving circuit, to make on and off frequencies of the PMOS transistor and the NMOS transistor increase row by row.

In the display panel of present disclosure, the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein the digital voltage generator comprises a first output end coupled to an input end of the PMOS transistor and a second output end coupled to an input end of the NMOS transistor for setting different output voltages applied to the pixel units to correspond to the signals outputted from the driving circuit, to make on and off frequencies of the PMOS transistor and the NMOS transistor increase row by row.

In the display panel of present disclosure, the digital voltage generator supplies ten or more bit levels of voltages.

In the display panel of present disclosure, the voltage control circuit comprises a digital voltage generator, comprising an output end coupled to the input end of the driving circuit and configured to set different output voltages applied to the pixel units to correspond to the signals outputted from the driving circuit, for making on and off frequencies of the input end and the output end of the driving circuit increase row by row.

Where the digital voltage generator supplies ten or more bit levels of voltages.

In the display panel of present disclosure, the digital voltage generator comprises a first output end coupled to an input end of the PMOS transistor and a second output end coupled to an input end of the NMOS transistor, for setting different output voltages applied to the pixel units to correspond to the signals outputted from the driving circuit, to make on and off frequencies of the PMOS transistor and the NMOS transistor increase row by row.

To reach the above-mentioned object, the pixel driving circuit of present disclosure further adopts the following technique:

A display panel, comprising:
a gate driving substrate comprising a pixel array and a circuit laying area located by the pixel array, the pixel array comprising pixel units arranged in rows;
a plurality of gate driving units disposed on the circuit laying area, and configured to output scanning signals to the pixel units of the pixel array;
a level shifter coupled to the plurality of gate driving units and configured to output a control signal;
a driving circuit comprising an input end, an output end coupled to the pixel units through the gate driving units, and a control end coupled to an output end of the level shifter for controlling the input end and the output end of the driving circuit to be on or off;
a voltage control circuit comprising an output end coupled to the input end of the driving circuit, and configured to set different voltages inputted into the input end of the driving circuit applied to the pixel units pixel units to correspond to a signal outputted from the driving circuit, for making an on and off frequency of the input end and the output end of the driving circuit increase row by row.

In the display panel of present disclosure, the voltage control circuit comprises:
a digital-to-analog converter configured to set different adjusting voltages to the pixel units to correspond to the signals outputted from the driving circuit, for making on and off frequencies of the input end and the output end of the driving circuit increase row by row; and
an adder comprising an output end coupled to the input end of the driving circuit, a first input end receiving a reference voltage, and a second input end coupled to the digital-to-analog converter.

In the display panel of present disclosure, the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein an input end of the PMOS transistor is coupled to the output end of the voltage control circuit, and/or an input end of the NMOS transistor is coupled to the output end of the driving circuit, for setting different adjusting voltages applied to the pixel units to correspond to the signals outputted from the driving circuit, to make on and off frequencies of the PMOS transistor and the NMOS transistor increase row by row.

In the display panel of present disclosure, the driving circuit comprises a digital voltage generator comprising an output end coupled to the input end of the driving circuit and configured to set different output voltages applied to the pixel units to correspond to the signals outputted from the driving circuit, for making on and off frequencies of the input end and the output end of the driving circuit increase row by row.

In the display panel of present disclosure, the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein the digital voltage generator comprises a first output end coupled to an input end of the PMOS transistor and a second output end coupled to an input end of the NMOS transistor for setting different output voltages applied to the pixel units to correspond to the signals outputted from the driving circuit, to make on and off frequencies of the PMOS transistor and the NMOS transistor increase row by row.

In the display panel of present disclosure, the voltage control circuit comprises a digital voltage generator comprising an output end coupled to the input end of the driving circuit.
Where the digital voltage generator is configured to set different output voltages applied to the pixel units to correspond to the signals outputted from the driving circuit, to make on and off frequencies of the input end and the output end of the driving circuit increase row by row:

In the display panel of present disclosure, the digital voltage generator comprises a first output end coupled to an input end of the PMOS transistor and a second output end coupled to an input end of the NMOS transistor for setting different output voltages applied to the pixel units to correspond to the signals outputted from the driving circuit, to make on and off frequencies of the PMOS transistor and the NMOS transistor increase row by row.

In the display panel of present disclosure, the digital voltage generator supplies ten or more bit levels of voltages.

The present disclosure further provides a gate signal control method for a display panel. The techniques are as follows.

A control method of gate signals for a display panel, wherein the display panel comprises a gate driving substrate, a plurality of gate driving units, a level shifter, and a driving circuit; the gate driving substrate comprises a pixel array and a circuit laying area located by the pixel array, the pixel array comprising pixel units arranged in rows; the plurality of driving units are disposed on the circuit laying area for outputting scanning signals to the pixel units of the pixel array;
the control method comprises:
coupling the level shifter with the plurality of gate driving units for outputting a control signal;
coupling a control end of the driving circuit with an output end of the level shifter for control an input end and an output end of the driving circuit to be on or off, coupling the output end of the driving circuit with the pixel units through the gate driving units;
controlling the voltage variation of the input end of the driving circuit according to pixel units to correspond to a signal outputted from the driving circuit, to make on and off frequencies of the input end and the output end of the driving circuit increase row by row.

In the gate signal control method for a display panel of present disclosure, the method comprises:
inputting a reference voltage to a first input end of an adder;
setting an adjusting voltage according to the pixel units to correspond to the signals outputted from the driving circuit;
inputting the adjusting voltage to a second input end of the adder; and
coupling an output end of the adder with the control end of the driving circuit to make on and off frequencies of the input end and the output end of the driving circuit increase row by row.

In the gate signal control method for a display panel of present disclosure, wherein the driving circuit comprises a PMOS transistor comprising a control end coupled to the output end of the level shifter and an output end coupled to the output end of the driving circuit; and an NMOS transistor comprising a control end coupled to the output end of the level shifter and an output end coupled to the output end of the driving circuit;
a control end of the NMOS transistor is coupled to the output end of the level shifter, an output end of the NMOS transistor is coupled to the voltage control circuit;
wherein the method comprises:
when the PMOS transistor is on, inputting a negative voltage of the adjusting voltage to the second input end of the adder, wherein the adjusting voltage decreases row by row;
when the NMOS transistor is on, inputting a positive voltage of the adjusting voltage to the second input end of the adder, wherein the adjusting voltage increases row by row.

In the gate signal control method for a display panel of present disclosure, the method comprises utilizing a digital voltage generator to set different voltages for inputting to the driving circuit according to the pixel units to correspond to a signal outputted by the driving circuit, to make on and off frequencies of the input end and the output end of the driving circuit increase row by row.

In the gate signal control method for a display panel of present disclosure, wherein the driving circuit comprises a PMOS transistor comprising a control end coupled to the output end of the level shifter and an output end coupled to the output end of the driving circuit; and an NMOS transistor comprising a control end coupled to the output end of the level shifter and an output end coupled to the output end of the driving circuit;
a control end of the NMOS transistor is coupled to the output end of the level shifter, an output end of the NMOS transistor is coupled to the voltage control circuit;
wherein the method comprises:
a first output end and a second output end of the digital voltage generator couple to an input end of the PMOS transistor and an input end of the NMOS transistor respectively;
when the PMOS transistor is on, making the voltage of the first output end of the digital voltage generator decrease row by row;
when the NMOS transistor is on, making the voltage of the second output end of the digital voltage generator increase row by row.

In the gate signal control method for a display panel of present disclosure, the method comprise utilizing a digital voltage generator to set different voltages for inputting to the driving circuit according to the pixel units to correspond to a signal outputted by the driving circuit, to make on and off frequencies of the input end and the output end of the driving circuit increase row by row.

In the gate signal control method for a display panel of present disclosure, the method comprises:
coupling a first output end and a second output end of the digital voltage generator with an input end of the PMOS transistor and an input end of the NMOS transistor respectively;
when the PMOS transistor is on, making the voltage of the first output end of the digital voltage generator decrease row by row;
when the NMOS transistor is on, making the voltage of the second output end of the digital voltage generator increase row by row.

In the gate signal control method for a display panel of present disclosure, the number of types of different voltages for inputting to the driving circuit is greater or equal to 1024 when utilizing the digital voltage generator to set different voltages for inputting to the driving circuit.

The voltage control circuit sets different voltages inputted into the input end of the driving circuit according to the pixel units to correspond to a signal outputted from the driving circuit, for making on and off frequencies of the input end and the output end of the driving circuit increase row by row. Therefore, the waveforms of CK that are outputted from the level shifter and received by each row of pixel units are consistent. The color deviation and unevenness of illuminance can be improved because the voltages of the gate signals of each row of pixel units on the gate driving substrate are consistent.

To make the above-mentioned content easier to be understood, the preferable embodiments are listed as follows together with drawings.

### DESCRIPTION OF DRAWINGS

The techniques and other beneficial effects will be obvious by the detailed description of present disclosure with the following drawings.

FIG. 1 illustrates a structure of a display panel of an embodiment of the present disclosure.

FIG. 2 illustrates a waveform diagram outputted by a level shifter of an embodiment of the present disclosure.

FIG. 3 illustrates a waveform diagram after the waveform of FIG. 2 arrives at the back of the panel.

FIG. 4 illustrates a waveform diagram outputted by a voltage control circuit of an embodiment of the present disclosure.

FIG. 5 illustrates a driving circuit of an embodiment of the present disclosure.

FIG. 6 illustrates the voltage control circuit of an embodiment of the present disclosure.

FIG. 7 illustrates another voltage control circuit of an embodiment of the present disclosure.

FIG. 8 illustrates a flowchart of the gate control method for a display panel of an embodiment of the present disclosure.

### DETAILED DESCRIPTION OF PREFERRED EMBODIMENTS

To further illustrate the technical means adopted by the present invention and the effects thereof, the following describes the preferable embodiments of the present invention and the accompanying drawings in detail. Obviously, the described embodiments are only a part but not all of the embodiments of the present invention. All other embodiments obtained by persons of ordinary skill in the art based on the embodiments of the present invention without creative efforts shall fall within the protection scope of the present invention.

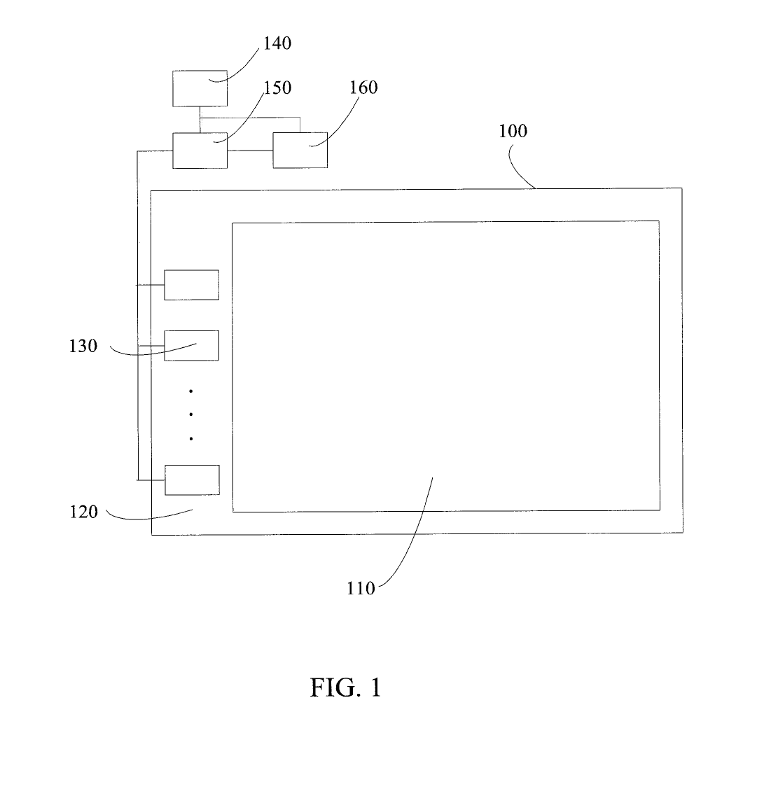

Please refer to FIG. 1. The present disclosure provides a display panel which includes a gate driving substrate 100, a plurality of gate driving units 130, a level shifter 140, a driving circuit 150, and voltage control circuit 160.

The gate driving substrate 100 includes a pixel array 110 and a circuit laying area 120 which is disposed near the pixel array. The pixel array 110 includes a plurality of rows of pixel units. The plurality of gate driving units 130 are disposed on the circuit laying area 120, and configured to output scanning signals to the pixel units of the pixel array 110. The level shifter 140 is coupled to the plurality of gate driving units, and is configured to output a control signal.

The driving circuit 150 includes an input end, an output end, and a control end. The output end of the driving circuit 150 is coupled to the pixel units through the gate driving units 130. The control end of the driving circuit 150 is coupled to an output end of the level shifter 140 for controlling the input end and the output end of the driving circuit to be on or off.

An output end of the voltage control circuit 160 is coupled to the input end of the driving circuit 150. The voltage control circuit 160 is configured to set different voltages inputted into the input end of the driving circuit according to the pixel units to correspond to a signal outputted from the driving circuit 150, so that on and off frequencies of the input end and the output end of the driving circuit 150 increase row by row.

The voltage control circuit 160 of present disclosure sets different voltages inputted into the input end of the driving circuit according to the pixel units to correspond to a signal outputted from the driving circuit 150, for making on and off frequencies of the input end and the output end of the driving circuit 150 increase row by row. Therefore, the waveforms of CK that outputted from the level shifter 140 and received by each row of pixel units are consistent. The color deviation and unevenness of illuminance can be improved because the gate signals of each row of pixel units on the gate driving substrate 100 are consistent.

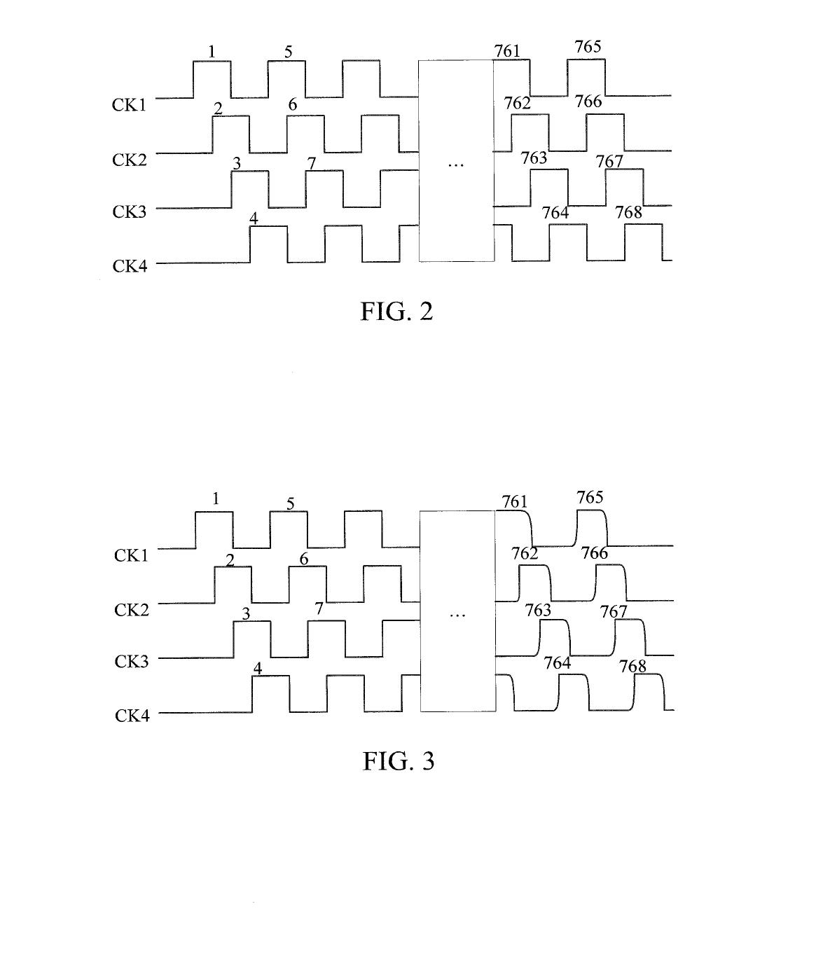

Please refer to FIG. 2. Take high definition (HD) devices for example, four clock signals (CK1-CK4) generate 768 pulses that the panel requires. Waveforms of these 768 pulses are consistent. However, please refer to FIG. 3, the pulse waveforms of each of the rows of the clock signals transmitted into the panel will differ from each other. The longer the wire route is, i.e. the further a clock signal goes, the more distorted the waveform will be.

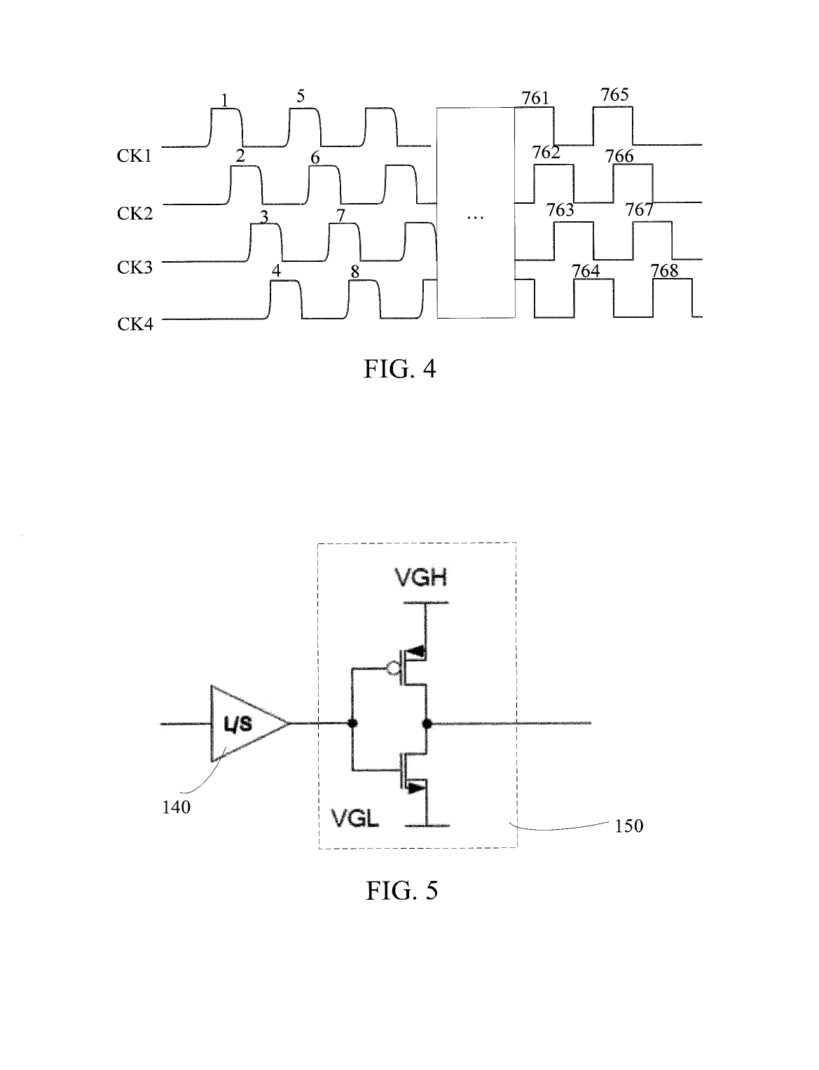

Please refer to FIG. 4. The present disclosure utilizes the built-in compensating functions of level shifters to adjust the different rows of clock signals regarding their impedance, so that the waveform outputted by the first level shifter will be substantially consistent with the waveform outputted by the last level shifter.

The circuit laying area 120 can be disposed on one side or both sides of the pixel array 110.

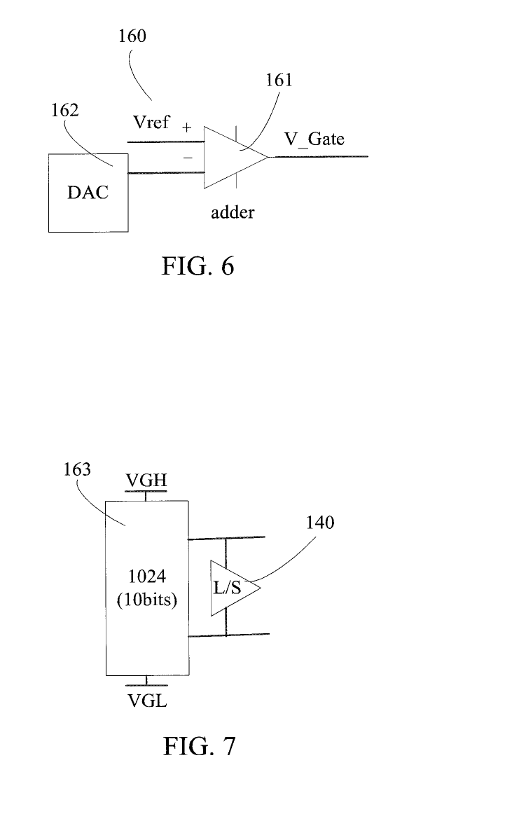

Please refer to FIG. 5 and FIG. 6. The voltage control circuit includes a digital-to-analog converter (DAC) 162 and an adder 161. An output end of the adder 161 is coupled to the input end of the driving circuit. A first input end of the adder 161 receives a reference voltage. A second input end of the adder 161 is coupled to the digital-to-analog converter (DAC) 162.

The digital-to-analog converter (DAC) 162 sets different adjusting voltages according to the pixel units to correspond to the signals outputted from the driving circuit, in order to make on and off frequencies of the input end and the output end of the driving circuit increase row by row.

Furthermore, the driving circuit includes a PMOS transistor and an NMOS transistor. A control end of the PMOS transistor is coupled to the output end of the level shifter 140. An output end of the PMOS transistor is coupled to the output end of the driving circuit.

A control end of the NMOS transistor is coupled to the output end of the level shifter 140. An output end of the NMOS transistor is coupled to the voltage control circuit 160.

An input end of the PMOS transistor is coupled to the output end of the voltage control circuit 160, and/or an input end of the NMOS transistor is coupled to the output end of the driving circuit, in order to set different adjusting voltages applied to the pixel units to correspond to the signals outputted from the driving circuit, to make on and off frequencies of the PMOS transistor and the NMOS transistor increase row by row.

Different impendences can be determined by the gate voltages of the transistors. When turning on the pixel units of different rows, the DAC is utilized to generate different voltages added to reference voltage Vref for generating the V_Gate signals that are required. When a negative voltage outputted from the DAC is applied for turning on the PMOS transistor, the on and off frequencies of each row will increase. When a positive voltage outputted from the DAC is applied for turning on the NMOS transistor, the on and off frequencies of each row will increase.

Please refer to FIG. 5 and FIG. 7. The voltage control circuit 160 includes a digital voltage generator 163. An output end of the digital voltage generator 163 is coupled to the input end of the driving circuit.

The digital voltage generator 163 sets different output voltages applied to the pixel units to correspond to the signals outputted from the driving circuit, to make on and off frequencies of the PMOS transistor and the NMOS transistor increase row by row.

Furthermore, the driving circuit includes a PMOS transistor and an NMOS transistor. A control end of the PMOS transistor is coupled to the output end of the level shifter 140. An output end of the PMOS transistor is coupled to the output end of the driving circuit.

A control end of the NMOS transistor is coupled to the output end of the level shifter 140. An output end of the NMOS transistor is coupled to the voltage control circuit 160.

The digital voltage generator 163 includes a first output end and a second output end which are coupled to the input end of the PMOS transistor and the input end of the NMOS transistor respectively, in order to set different output voltages applied to the pixel units to correspond to the signals outputted from the driving circuit, so that on and off frequencies of the PMOS transistor and the NMOS transistor increase row by row.

There are a total of 10 bits (1024) of voltage levels between VGH and VGL. The above-mentioned compensating effect can be implemented by setting the voltage for turning on the PMOS transistor to different bits. This will result in a difference to turning-on speed. That is, during turning on the PMOS transistor, the on and off frequencies will increase due to the decrease of impedance because the bits level of the outputted voltage is lower. While turning on the NMOS transistor, the on and off frequencies will increase due to the decrease of impedance because the bits level of outputted voltage is higher.

The above-mentioned technique can be applied from the first row. The on and off frequencies at the beginning, i.e. the first row, are lower, and then the frequencies of later rows increase, so that the gate voltage applied to each row will be consistent. Thus, the color deviation and unevenness (i.e., mura) of illuminance can be improved.

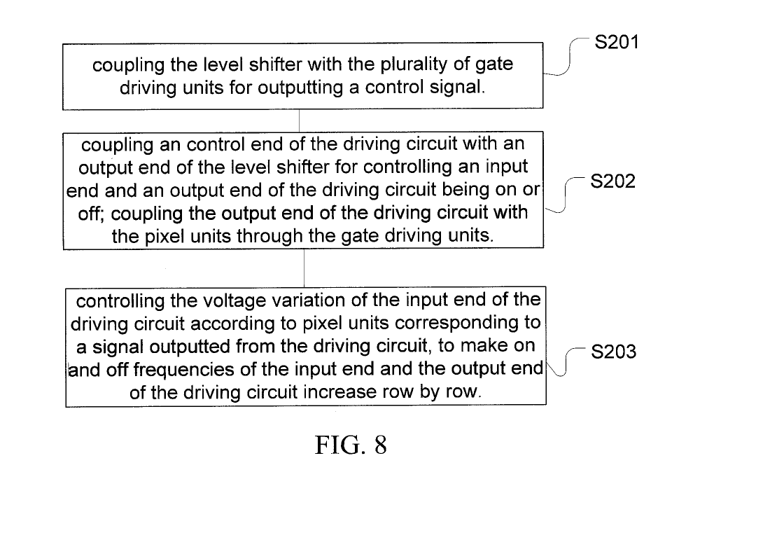

Please refer to FIG. 8, the present disclosure further discloses a gate signal control method for a display panel. The display panel includes a gate driving substrate, a plurality of gate driving units, a level shifter, and a driving circuit. The gate driving substrate includes a pixel array and a circuit laying area. The circuit laying area is located by the pixel array. The pixel array includes a plurality of rows of pixel units. The plurality of driving units are disposed on the circuit laying area and configured to output scanning signals to the pixel units of the pixel array.

The control method includes steps S201-S203.

Step S201: coupling the level shifter with the plurality of gate driving units for outputting a control signal.

Step S202: coupling a control end of the driving circuit with an output end of the level shifter for controlling an input end and an output end of the driving circuit to be on or off; coupling the output end of the driving circuit with the pixel units through the gate driving units.

Step S203: controlling the voltage variation of the input end of the driving circuit according to pixel units to correspond to a signal outputted from the driving circuit, to make on and off frequencies of the input end and the output end of the driving circuit increase row by row.

The present disclosure sets and inputs different voltages, which are outputted from the driving circuit, into the driving circuit according to the pixel units to correspond to a signal outputted from the driving circuit, for making on and off frequency of the input end and the output end of the driving circuit increase row by row. Therefore, the waveforms of CK that outputted from the level shifter and received by each row of pixel units are consistent. Thus, color deviation and unevenness of illuminance can be improved because the voltages of gate signals of each row of pixel units on the gate driving substrate are consistent.

Selectively, the method includes: inputting a reference voltage to a first input end of an adder; setting a adjusting voltage according to the pixel units to correspond to the signal outputted from the driving circuit; inputting the adjusting voltage to a second input end of the adder; coupling an output end of the adder with the control end of the driving circuit to make on and off frequencies of the input end and the output end of the driving circuit increase row by row.

Furthermore, the method further includes: the driving circuit includes a PMOS transistor and an NMOS transistor. A control end of the PMOS transistor is coupled to the output end of the level shifter. An output end of the PMOS transistor is coupled to the output end of the driving circuit.

A control end of the NMOS transistor is coupled to the output end of the level shifter. An output end of the NMOS transistor is coupled to the output end of the driving circuit.

When the PMOS transistor is on, a negative voltage of the adjusting voltage is inputted to the second input end of the adder, where the adjusting voltage gradually decreases row by row.

When the NMOS transistor is on, a positive voltage of the adjusting voltage is inputted to the second input end of the adder, where the adjusting voltage increases.

Different impendences can be set by controlling the gate voltages of the transistors. When turning on the pixel units of different rows, the DAC is utilized to generate different voltages added to reference voltage Vref for generating the V_Gate signals that are required. When a negative voltage outputted from the DAC is applied for turning on the PMOS transistor, the on and off frequencies of each row will increase. When a positive voltage outputted from the DAC is applied for turning on the NMOS transistor, the on and off frequencies of each row will increase.

The method further includes: utilizing a digital voltage generator to set different voltage for inputting to the driving circuit according to the pixel units to correspond to a signal outputted by the driving circuit, to make on and off frequencies of the input end and the output end of the driving circuit increase row by row.

Furthermore, the method further includes: the driving circuit includes a PMOS transistor and an NMOS transistor. A control end of the PMOS transistor is coupled to the output end of the level shifter. An output end of the PMOS transistor is coupled to the output end of the driving circuit.

A control end of the NMOS transistor is coupled to the output end of the level shifter. An output end of the NMOS transistor is coupled to the output end of the driving circuit.

A first output end and a second output end of the digital voltage generator are coupled to an input end of the PMOS transistor and an input end of the NMOS transistor, respectively.

When the PMOS transistor is on, the voltage of the first output end of the digital voltage generator gradually decreases row by row.

When the NMOS transistor is on, the voltage of the second output end of the digital voltage generator gradually increases row by row.

There are a total of 10 bits (1024) of voltage levels between VGH and VGL. The above-mentioned compensating effect can be implemented by setting the voltage for turning on the PMOS transistor to different bits. This will result in a difference in turning-on speed. That is, during turning on the PMOS transistor, the on and off frequencies will increase due to the decrease of impedance that results from the decrease of bits level of outputted voltage. While turning on the NMOS transistor, the on and off frequencies will increase due to the decrease of impedance that results from the increase of bits level of outputted voltage.

In conclusion, although this disclosure has been disclosed through the preferable embodiments above, the preferable embodiments above are not utilized to limit this disclosure. One having ordinary skills can change and modify without violating the concepts and scope of this disclosure. Therefore, the scope that this disclosure protects is based on the scope defined by the claims.

1. A display panel, comprising:
a gate driving substrate, comprising a pixel array and a circuit laying area located near the pixel array, the pixel array comprising pixel units arranged in rows;
a plurality of gate driving units disposed on the circuit laying area, and configured to output scanning signals to the pixel units of the pixel array;
a level shifter coupled to the plurality of gate driving units and configured to output a control signal;
a driving circuit comprising an input end, an output end coupled to the pixel units through the gate driving units, and a control end coupled to an output end of the level shifter for controlling the input end and the output end of the driving circuit to be on or off;
a voltage control circuit comprising an output end coupled to the input end of the driving circuit, and configured to input different voltages into the input end of the driving circuit according to the pixel units, to correspond to a signal output from the driving circuit, for making on and off frequencies of the gate driving units increase row by row;
a digital voltage generator comprising an output end coupled to the input end of the driving circuit and configured to set different output voltages applied to the pixel units to correspond to the signal outputted from the driving circuit, for making on and off frequencies of the gate driving units increase row by row; wherein the voltage control circuit comprises:
an digital-to-analog converter configured to set different adjusting voltages to the pixel units to correspond to the signal output from the driving circuit, for making on and off frequencies of the gate driving units increase row by row; and
an adder comprising an output end coupled to the input end of the driving circuit, a first input end receiving a reference voltage, and a second input end coupled to the digital-to-analog converter.

2. The display panel according to claim 1, wherein the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein an input end of the PMOS transistor is coupled to the output end of the voltage control circuit, and/or an input end of the NMOS transistor is coupled to the output end of the driving circuit, for setting different adjusting voltages applied to the pixel units to correspond to the signal outputted from the driving circuit, to make on and off frequencies of the gate driving unit increase row by row.

3. The display panel according to claim 1, wherein the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein the digital voltage generator comprises a first output end coupled to an input end of the PMOS transistor and a second output end coupled to an input end of the NMOS transistor, for setting different output voltages applied to the pixel units to correspond to the signal outputted from the driving circuit, to make on and off frequencies of the gate driving unit increase row by row.

4. The display panel according to claim 1, wherein the digital voltage generator supplies ten or more bit levels of voltages.

5. A display panel, comprising:
a gate driving substrate comprising a pixel array and a circuit laying area located by the pixel array, the pixel array comprising pixel units arranged in rows;
a plurality of gate driving units disposed on the circuit laying area, and configured to output scanning signals to the pixel units of the pixel array;
a level shifter coupled to the plurality of gate driving units and configured to output a control signal;
a driving circuit comprising an input end, an output end coupled to the pixel units through the gate driving units, and a control end coupled to an output end of the level shifter for controlling the input end and the output end of the driving circuit to be on or off;
a voltage control circuit comprising an output end coupled to the input end of the driving circuit, and configured to set different voltages inputted into the input end of the driving circuit applied to the pixel units pixel units to correspond to a signal outputted from the driving circuit, for making on and off frequency of the gate driving unit increase row by row.

6. The display panel according to claim 5, wherein the voltage control circuit comprises:
an digital-to-analog converter configured to set different adjusting voltages to the pixel units to correspond to the signal outputted from the driving circuit, for making on and off frequencies of the gate driving unit increase row by row; and
an adder comprising an output end coupled to the input end of the driving circuit, a first input end receiving a reference voltage, and a second input end coupled to the digital-to-analog converter.

7. The display panel according to claim 6, wherein the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein an input end of the PMOS transistor is coupled to the output end of the voltage control circuit, and/or an input end of the NMOS transistor is coupled to the output end of the driving circuit, for setting different adjusting voltages applied to the pixel units to correspond to the signal outputted from the driving circuit, to make on and off frequencies of the gate driving unit.

8. The display panel according to claim 5, wherein the display panel comprises a digital voltage generator, comprising an output end coupled to the input end of the driving circuit and configured to set different output voltages applied to the pixel units to correspond to the signal outputted from the driving circuit, for making on and off frequencies of the gate driving unit increase row by row.

9. The display panel according to claim 8, wherein the driving circuit comprises:
a PMOS transistor comprising a control end coupled to the output end of the level shifter and an output end coupled to the output end of the driving circuit; and
an NMOS transistor comprising a control end coupled to the output end of the level shifter and a output end coupled to the voltage control circuit;
wherein the digital voltage generator comprises a first output end coupled to an input end of the PMOS transistor and a second output end coupled to an input end of the NMOS transistor for setting different output voltages applied to the pixel units to correspond to the signal outputted from the driving circuit, to make on and off frequencies of the gate driving unit increase row by row.

10. The display panel according to claim 8, wherein the digital voltage generator supplies ten or more bit levels of voltages.

11. The display panel according to claim 7, wherein the display panel comprises:
a digital voltage generator comprising an output end coupled to the input end of the driving circuit and configured to set different output voltages applied to the pixel units to correspond to the signal outputted from the driving circuit, to make on and off frequencies of the gate driving unit increase row by row;
wherein the digital voltage generator supplies ten or more bit levels of voltages.

12. The display panel according to claim 11, wherein the digital voltage generator comprises a first output end coupled to an input end of the PMOS transistor and a second output end coupled to an input end of the NMOS transistor for setting different output voltages applied to the pixel units to correspond to the signal outputted from the driving circuit, to make on and off frequencies of the gate driving unit increase row by row.

13. A control method of gate signals for a display panel, wherein the display panel comprises a gate driving substrate, a plurality of gate driving units, a level shifter, and a driving circuit; the gate driving substrate comprises a pixel array and a circuit laying area located by the pixel array, the pixel array comprising pixel units arranged in rows; the plurality of driving units disposed on the circuit laying area, and configured to output scanning signals to the pixel units of the pixel array;
wherein the control method comprises:
coupling the level shifter with the plurality of gate driving units for outputting a control signal;
coupling a control end of the driving circuit with an output end of the level shifter for controlling an input end and an output end of the driving circuit to be on or off, coupling the output end of the driving circuit with the pixel units through the gate driving units;
controlling the voltage variation of the input end of the driving circuit according to pixel units to correspond to a signal outputted from the driving circuit, to make on and off frequencies of the gate driving unit increase row by row.

14. The control method of gate signals for a display panel according to claim 13, wherein the method further comprises:
inputting a reference voltage to a first input end of an adder;
setting a adjusting voltage according to the pixel units to correspond to the signal outputted from the driving circuit;
inputting the adjusting voltage to a second input end of the adder; and
coupling an output end of the adder with the control end of the driving circuit to make on and off frequencies of the gate driving unit increase row by row.

15. The control method of gate signals for a display panel according to claim 13, wherein the driving circuit comprises a PMOS transistor comprising a control end coupled to the output end of the level shifter and an output end coupled to the output end of the driving circuit; and an NMOS transistor comprising a control end coupled to the output end of the level shifter and an output end coupled to the output end of the driving circuit;
a control end of the NMOS transistor is coupled to the output end of the level shifter, an output end of the NMOS transistor is coupled to the voltage control circuit;
wherein the method further comprises:
when the PMOS transistor is on, inputting an negative voltage of the adjusting voltage to the second input end of the adder, wherein the adjusting voltage becomes lower;
when the NMOS transistor is on, inputting a positive voltage of the adjusting voltage to the second input end of the adder, wherein the adjusting voltage becomes higher.

16. The control method of gate signals for a display panel according to claim 13, wherein the method further comprises:
utilizing a digital voltage generator to set different voltage for inputting to the driving circuit according to the pixel units to correspond to a signal outputted by the driving circuit, to make on and off frequencies of the gate driving unit increase row by row.

17. The control method of gate signals for a display panel according to claim 13, wherein the driving circuit comprises a PMOS transistor comprising a control end coupled to the output end of the level shifter and an output end coupled to the output end of the driving circuit; and an NMOS transistor comprising a control end coupled to the output end of the level shifter and an output end coupled to the output end of the driving circuit;
a control end of the NMOS transistor is coupled to the output end of the level shifter, an output end of the NMOS transistor is coupled to the voltage control circuit;
a first output end and a second output end of the digital voltage generator couple to an input end of the PMOS transistor and an input end of the NMOS transistor respectively;
wherein the method further comprises:
when the PMOS transistor is on, making the voltage of the first output end of the digital voltage generator decrease row by row;
when the NMOS transistor is on, making the voltage of the second output end of the digital voltage generator increase row by row.

18. The control method of gate signals for a display panel according to claim 16, wherein the number of the types of the different voltage for inputting to the driving circuit is greater or equal to 1024 when utilizing the digital voltage generator to set different voltage for inputting to the driving circuit.

19. The control method of gate signals for a display panel according to claim 15, wherein the method further comprises: utilizing a digital voltage generator to set different voltage for inputting to the driving circuit according to the pixel units to correspond to a signal outputted by the driving circuit, to make on and off frequencies of the gate driving unit increase row by row.

20. The control method of gate signals for a display panel according to claim 19, wherein the method further comprises:
coupling a first output end and a second output end of the digital voltage generator with an input end of the PMOS transistor and an input end of the NMOS transistor, respectively;
when the PMOS transistor is on, making the voltage of the first output end of the digital voltage generator decrease row by row;
when the NMOS transistor is on, making the voltage of the second output end of the digital voltage generator increase row by row.
